(19) United States
(12) Patent Application Publication
(10) Pub. No.: US 2013/0210186 A1
(43) Pub. Date: Aug. 15, 2013

(54) METHOD FOR MANUFACTURING FLEXIBLE SOLAR CELL MODULE

(71) Applicants: Hiroshi Hiraike, Osaka (JP); Masahiro Asuka, Osaka (JP); Takahiko Sawada, Osaka (JP); Kiyomi Uenomachi, Osaka (JP); Takahiro Nomura, Osaka (JP)

(72) Inventors: Hiroshi Hiraike, Osaka (JP); Masahiro Asuka, Osaka (JP); Takahiko Sawada, Osaka (JP); Kiyomi Uenomachi, Osaka (JP); Takahiro Nomura, Osaka (JP)

(73) Assignee: Sekisui Chemical Co., Ltd., Osaka (JP)

(21) Appl. No.: 13/821,593

(22) PCT Filed: Sep. 20, 2011
(86) PCT No.: PCT/JP2011/071366

§ 371 Date: Apr. 24, 2013

(30) Foreign Application Priority Data
Nov. 18, 2010 (JP) 2010-257991

(51) Int. Cl. H01L 31/0203; H01L 31/18

(52) U.S. Cl. CPC H01L 31/0203; H01L 31/18
USPC 438/64

(57) ABSTRACT

An object of the present invention is to provide a method for producing a flexible solar cell module which makes it possible to suitably produce flexible solar cell modules in which a solar cell element and a solar cell encapsulant sheet are well adhered to each other by encapsulating a solar cell by roll-to-roll processing in a continuous manner without the need to perform a crosslinking process and without causing wrinkles and curls. The present invention is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls, the solar cell encapsulant sheet including a fluoropolymer sheet and an adhesive layer on the fluoropolymer sheet, the adhesive layer including at least one ethylene copolymer selected from the group consisting of ethylene-unsaturated carboxylic acid copolymers and ionomers of ethylene-unsaturated carboxylic acid copolymers, the ethylene copolymer including 10 to 25% by weight of unsaturated carboxylic acid units.

### TECHNICAL FIELD

The present invention relates to a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### BACKGROUND ART

Solar cell modules known so far are: rigid solar cell modules that include a glass substrate; and flexible solar cell modules that include a thin film substrate of stainless steel or a substrate made of a heat resistant polymer material such as polyimide or polyester. In recent years, flexible solar cell modules have been attracting attention because they are easy to transport and install due to their thin and lightweight designs, and have high impact resistance.

A flexible solar cell module is a laminate of a flexible solar cell element and solar cell encapsulant sheets encapsulating the upper and lower surfaces of the flexible solar cell element. The flexible solar cell element is a laminate created by stacking, on a flexible substrate, a thin layer such as a photoelectric conversion layer made of a silicon semiconductor, a compound semiconductor, or the like which generates a current when exposed to light.

The solar cell encapsulant sheets serve to mitigate impacts from the exterior and protect the solar cell element from corrosion, and consist of a transparent sheet and an adhesive layer on the transparent sheet. The adhesive layers, which are designed to encapsulate the solar cell element, have been made using ethylene-vinyl acetate (EVA) resins (for example, Patent Literature 1).

The use of EVA resins, however, has some problems such as an extended production time and generation of an acid because it requires a crosslinking process. In view of these problems, some attempts have been made to form an adhesive layer of a solar cell encapsulant sheet using a non-EVA resin such as a silane-modified olefin resin (for example, Patent Literature 2).

Flexible solar cell modules have been conventionally produced by a method involving cutting a flexible solar cell element and solar cell encapsulant sheets into desired shapes, stacking the cut pieces, and bonding them together into an integrated laminate in a static state by vacuum laminating. Such vacuum laminating methods take a long time to finish bonding, and therefore are disadvantageously less efficient in producing solar cell modules.

One of methods for producing a flexible solar cell module under study is roll-to-roll processing that is advantageous for mass production (for example, Patent Literature 3).

The roll-to-roll processing is a technique to produce a flexible solar cell module in a continuous manner, and uses a roll of a solar cell encapsulant film sheet. The solar cell encapsulant sheet is unrolled, and subjected to thermocompression bonding in which the solar cell encapsulant sheet is pressed together with a solar cell element between a pair of rolls to encapsulate the solar cell element.

The roll-to-roll processing is expected to enable continuous and remarkably efficient production of flexible solar cell modules.

However, the roll-to-roll processing, when used to produce a flexible solar cell module by encapsulating a flexible solar cell element with a conventional solar cell encapsulant sheet, causes some problems that strikingly reduce the production efficiency, such as the need to perform a crosslinking process and occurrence of wrinkles and curls upon thermocompression bonding of the flexible solar cell element and the solar cell encapsulant sheet between rolls, and other problems such as insufficient adhesion between the flexible solar cell element and the solar cell encapsulant sheet.

In this context, there has been a demand for a method that maintains the high production efficiency of the roll-to-roll processing enough, prevents wrinkles and curls, and allows a flexible solar cell element to be well encapsulated in a continuous manner.

### CITATION LIST

### Patent Literature

Patent Literature 1: Japanese Kokai Publication No. Hei-07-297439 (JP-A H07-297439)
Patent Literature 2: Japanese Kokai Publication No. 2004-214641 (JP-A 2004-214641)
Patent Literature 3: Japanese Kokai Publication No. 2000-294815 (JP-A 2000-294815)

### SUMMARY OF INVENTION

### Technical Problem

In view of the above-mentioned situation, the present invention provides a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### Solution to Problem

The present invention is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls, the solar cell encapsulant sheet including a fluoropolymer sheet and an adhesive layer on the fluoropolymer sheet, the adhesive layer including at least one ethylene copolymer selected from the group consisting of ethylene-unsaturated carboxylic acid copolymers and ionomers of ethylene-unsaturated carboxylic acid copolymers.

The following description is offered to illustrate the present invention in detail.

The present invention relates to production of a flexible solar cell module in which a solar cell element and a solar cell encapsulant sheet that includes an adhesive layer containing specific components and a fluoropolymer sheet are well adhered to each other by encapsulating the solar cell element with the solar cell encapsulant sheet in a continuous manner by roll-to-roll processing without causing wrinkles and curls.

Specifically, the present inventors found that in the case that a solar cell encapsulant sheet that includes a fluoropolymer sheet and an adhesive layer containing a specific ethylene copolymer on the fluoropolymer sheet is used to encapsulate a solar cell element, the encapsulation can be accomplished in a comparatively short time by thermocompression bonding at a comparatively low temperature without the need to perform a crosslinking process, and in a continuous manner by roll-to-roll processing, thereby completing the present invention.

The method for producing a flexible solar cell module of the present invention includes thermocompression bonding of a solar cell encapsulant sheet to at least a light-receiving surface of a solar cell element that includes a flexible substrate and a photoelectric conversion layer on the substrate by pressing them between a pair of heating rolls.

The solar cell encapsulant sheet includes an adhesive layer containing at least one ethylene copolymer selected from the group consisting of ethylene-unsaturated carboxylic acid copolymers and ionomers of ethylene-unsaturated carboxylic acid copolymers on a fluoropolymer sheet.

The present invention makes use of a solar cell encapsulant sheet that includes such art adhesive layer containing a specific resin to suitably produce flexible solar cell modules by roll-to-roll processing.

The ethylene copolymer is at least one selected from the group consisting of ethylene-unsaturated carboxylic acid copolymers and ionomers of ethylene-unsaturated carboxylic acid copolymers.

The ethylene-unsaturated carboxylic acid copolymers are copolymers containing at least ethylene copolymerized units and unsaturated carboxylic acid copolymerized units.

Examples of unsaturated carboxylic acids include acrylic acid, methacrylic acid, maleic acid, monomethyl maleate, monoethyl maleate, phthalic acid, citraconic acid, and itaconic acid. Any combination of two or more of these is also acceptable. In particular, preferred unsaturated carboxylic acids are acrylic acid and/or methacrylic acid because they enable molecules to be cross-linked efficiently.

The ethylene-unsaturated carboxylic acid copolymers encompass not only copolymers consisting of ethylene and an unsaturated carboxylic acid but also multinary copolymers containing other copolymerized units as desired.

Additionally, the ethylene-unsaturated carboxylic acid copolymers may cover copolymers further containing (meth)acrylic acid ester units as the third component.

The use of such a trinary copolymer consisting of ethylene units, unsaturated carboxylic acid units, and (meth)acrylic acid ester units allows to control the physical properties such as the melting point and adhesion, and therefore allows to make planning for more successful flexible solar cell module production.

The term “(meth)acrylic acid ester” herein is intended to include acrylic acid esters and methacrylic acid esters.

The (meth)acrylic acid ester units are preferably units of at least one selected from methyl(meth)acrylate, ethyl(meth)acrylate, and butyl(meth)acrylate for cost and polymerizability reasons. In particular, acrylic acid esters are preferable because of their suitability for lamination. Specifically, n-butyl acrylate, isobutyl acrylate, and ethyl acrylate are preferable.

The ethylene-unsaturated carboxylic acid copolymers can be prepared by radical copolymerization of ethylene and an unsaturated carboxylic acid optionally with monomers such as (meth)acrylic acid esters by common methods.

The ionomers of ethylene-unsaturated carboxylic acid copolymers are those prepared by partially or fully neutralizing the unsaturated carboxylic acid groups of the ethylene-unsaturated carboxylic acid copolymers with metal ions.

Examples of such metal ions include sodium ion, potassium ion, lithium ion, zinc ion, magnesium ion, and calcium ion. In particular, sodium ion and zinc ion are preferable because they are less hygroscopic.

The neutralization degree of the ionomers of ethylene-unsaturated carboxylic acid copolymers is preferably not more than 30 mol %, and more preferably not more than 20 mol % in terms of providing rigidity.

The ionomers of ethylene-unsaturated carboxylic acid copolymers can be prepared by neutralizing the ethylene-unsaturated carboxylic acid copolymers by common methods.

The ethylene copolymer contains 10 to 25% by weight of unsaturated carboxylic acid units. If the amount of unsaturated carboxylic acid units is less than 10% by weight, a composition containing it does not provide good rigidity and sufficient adhesion at low temperatures, and therefore may fail to sufficiently bond the solar cell element and the solar cell encapsulant sheet, and to sufficiently encapsulate the solar cell element. If the amount of unsaturated carboxylic acid units is more than 25% by weight, the adhesive layer becomes fragile and has low flexibility. In this case, resulting flexible solar cell modules are more prone to wrinkles and curls. The preferable lower limit of the amount of unsaturated carboxylic acid units is 15% by weight, and the preferable upper limit thereof is 20% by weight.

In the case that the ethylene copolymer contains (meth)acrylic acid ester units as copolymerised units, the amount of (meth)acrylic acid ester units is preferably not more than 25% by weight. If the amount of (meth)acrylic acid ester units is more than 25% by weight, the solar cell encapsulant sheet may be poor in heat resistance. The more preferable upper limit of the amount of (meth)acrylic acid ester units is 20% by weight.

The ethylene copolymer preferably has a maximum peak temperature (Tm) of 80 to 125° C. as determined from an endothermic curve obtained by differential scanning calorimetry. If the maximum peak temperature (Tm) determined from an endothermic curve is lower than 80° C., the solar cell encapsulant sheet may be less heat resistant. If the maximum peak temperature (Tm) determined from an endothermic curve is higher than 125° C., the solar cell encapsulant sheet may require a longer period of heating in the encapsulation process, leading to lower production efficiency of flexible solar cell modules or failing to sufficiently encapsulate the solar cell element. The maximum peak temperature (Tm) of an endothermic curve is more preferably 83 to 110° C.

The maximum peak temperature (Tm) of an endothermic curve obtained by differential scanning calorimetry is measured in accordance with the method specified in JIS K7121.

The ethylene copolymer preferably has a melt flow rate (MFR) of 0.5 g/10 min to 29 g/10 min. If the melt flow rate is less than 0.5 g/10 min, uneven portions may be formed on the flexible solar cell encapsulant sheet in the process of forming the encapsulant sheet, resulting in production of a flexible solar cell module that tends to curl. If the melt flow rate is more than 29 g/10 min, the possibility of drawdown in the process of forming the solar cell encapsulant sheet is high, in other words, it is difficult to form a sheet with an even thickness. This case may also result in production of a flexible solar cell module that tends to curl, or formation of pinholes or the like in the solar cell encapsulant sheet which may cause a resulting flexible solar cell module to entirely lose insulation properties. The melt flow rate is more preferably 2 g/10 min to 10 g/10 min.

The melt flow rate of the ethylene copolymer is measured under a load of 2.16 kg in accordance with ASTM D1238, which is used to measure the melt flow rate of polyethylene resins.

The ethylene copolymer preferably has a viscoelastic storage modulus at 30° C. of not more than 5×10⁸ Pa. If the viscoelastic storage modulus at 30° C. is more than 5×10⁸ Pa, the solar cell encapsulant sheet may be less flexible, and therefore may be difficult to handle. Additionally, rapid heating of the solar cell encapsulant sheet may be required to encapsulate a solar cell element with the solar cell encapsulant sheet in the process of producing a flexible solar cell module. If the viscoelastic storage modulus at 30° C. is too low, the solar cell encapsulant sheet may become sticky at room temperature, and therefore may be difficult to handle. Accordingly, the lower limit thereof is preferably 1×10⁷ Pa. The upper limit is more preferably 3×10⁸ Pa.

The ethylene copolymer preferably has a viscoelastic storage modulus at 100° C. of not more than 5×10⁶ Pa. If the viscoelastic storage modulus at 1000° C. is more than 5×10⁶ Pa, the adhesion of the solar cell encapsulant sheet to the solar cell element may be weak.

If the viscoelastic storage modulus at 100° C. is too low, the solar cell encapsulant sheet may significantly flow when pressing force is applied to encapsulate a solar cell element with the solar cell encapsulant sheet in the process of producing a solar cell module. In this case, the thickness of the solar cell encapsulant sheet may become significantly uneven. Accordingly, the lower limit thereof is preferably 1×10⁴ Pa. The upper limit is more preferably 4×10⁶ Pa.

The viscoelastic storage modulus of the ethylene copolymer is measured by a testing method for dynamic properties in accordance with JIS K6394.

The adhesive layer preferably further contains a silane compound. The presence of the silane compound improves the adhesion between the adhesive layer and the surface of the solar cell.

Examples of such silane compounds include alkoxysilanes. Among the alkoxysilanes, trialkoxysilanes represented by R¹Si(OR²)₃ and/or dialkoxysilanes represented by R³R⁴Si(OR²)₂ are preferable.

R² is not particularly limited, provided that it is an alkyl group containing 1 to 3 carbon atoms. Examples thereof include methyl, ethyl, and propyl. Preferred is methyl.

Examples of trialkoxysilanes represented by R¹Si(OR)₃ include 3-glycidoxypropyltrimethoxysilane, 3-glycidoxypropyltriethoxysilane, 3-glycidoxypropyltripropoxysilane, 3-glycidoxypropyl methyldimethoxysilane, 3-glycidoxypropyl methyldiethoxysilane, 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane. Preferred is 3-glycidoxypropyltrimethoxysilane.

Preferred examples of dialkoxysilanes represented by R³R⁴Si(OR²)₂ include dialkoxysilanes having an amino group.

Examples of dialkoxysilanes having an amino group include N-2-(aminoethyl)-3-aminopropylalkyldialkoxysilanes such as N-2-(aminoethyl)-3-aminopropylmethyldimethoxysilane and N-2-(aminoethyl)-3-aminopropylmethyldiethoxysilane, 3-aminopropylalkyldialkoxysilanes such as 3-aminopropylmethyldimethoxysilane and 3-aminopropylmethyldiethoxysilane, N-phenyl-3-aminopropylmethyldimethoxysilane, and N-phenyl-3-aminopropylmethyldiethoxysilane.

Among these, N-2-(aminoethyl)-3-aminopropylmethyldimethoxysilane is preferred because it is industrially easily available.

The silane compound content in the adhesive layer is preferably 0.4 to 15 parts by weight relative to 100 parts by weight of the ethylene copolymer.

If the silane compound content is out of the range, the adhesion of the solar cell encapsulant sheet may be weak.

The lower limit of the silane compound content is mere preferably 0.4 parts by weight relative to 100 parts by weight of the ethylene copolymer, and the upper limit thereof is more preferably 1.5 parts by weight.

The adhesive layer may further contain other additives such as photostabilizers, ultraviolet absorbers, and heat stabilizers in amounts that do not impair the physical properties of the adhesive layer.

Examples of methods for forming the adhesive layer include a method involving melting predetermined ratios (weight basis) of the ethylene copolymer and the silane compound, and optionally predetermined ratios (weight basis) of additives in an extruder, kneading the mixture, and extruding the mixture into a sheet from the extruder.

The thickness of the adhesive layer is preferably 80 to 700 μm. If the thickness of the adhesive layer is less than 80 μm, the adhesive layer may fail to ensure the insulative properties of flexible solar cell modules. If the thickness of the adhesive layer is more than 700 μm, flexible solar cell modules with impaired flame retardancy or heavy flexible solar cell modules may be provided. Additionally, it is disadvantageous for cost reasons. The thickness of the adhesive layer is more preferably 150 to 400 μm.

In the solar cell encapsulant sheet, the adhesive layer is formed on a fluoropolymer sheet.

The fluoropolymer sheet is not particularly limited, provided that it is excellent in transparency, heat resistance, and flame retardancy. However, the fluoropolymer sheet preferably includes at least one fluoropolymer selected from the group consisting of tetrafluoroethylene-ethylene copolymers (ETFE), ethylene-chlorotrifluoroethylene resins (ECTFE), polychlorotrifluoroethylene resins (PCTFE), polyvinylidene fluoride resins (PVDF), tetrafluoroethylene-perfluoroalkyl vinyl ether copolymers (FAP), polyvinyl fluoride resins (PVF), tetrafluoroethylene-hexafluoropropylene copolymers (FEP), vinylidene fluoride-hexafluoropropylene copolymers (PVDF-HFP), and a mixture of polyvinylidene fluoride and polymethylmethacrylate (PVDF/PMMA).

In particular, the fluoropolymer is more preferably polyvinylidene fluoride resins (PVDF), tetrafluoroethylene-ethylene copolymers (ETFE), or polyvinyl fluoride resins (PVF) because of their better heat resistance and transparency.

The thickness of the fluoropolymer sheet is preferably 10 to 100 μm. If the thickness of the fluoropolymer sheet is less than 10 μm, the fluoropolymer sheet may fail to ensure the insulative properties, and may impair the flame retardancy. If the thickness of the fluoropolymer sheet is more than 100 μm, heavy flexible solar cell modules may be provided, which is disadvantageous for cost reasons. The thickness of the fluoropolymer sheet is more preferably 15 to 80 μm.

The solar cell encapsulant sheet can be formed by integrating the fluoropolymer sheet and the adhesive layer into a laminate. The integration into a laminate can be accomplished by any methods, and examples of integration methods include a method in which the fluoropolymer sheet is formed on one surface of the adhesive layer by extrusion lamination, and a method in which the adhesive layer and the fluoropolymer sheet are formed by coextrusion. In particular, it is preferable to simultaneously form the sheet and the layer as a laminate by coextrusion.

The extrusion temperature in the coextrusion process is preferably higher than the melting point of the fluoropolymer and the ethylene-unsaturated carboxylic acid copolymer or ionomer thereof by 30° C. or more and is preferably lower than the decomposition temperature thereof by 30° C. or more.

As described above, the solar cell encapsulant sheet is preferably an integrated laminate formed by simultaneously forming the adhesive layer and the fluoropolymer sheet by coextrusion.

The solar cell encapsulant sheet preferably has an embossed surface. In particular, a surface of the solar cell encapsulant sheet which is to be a light-receiving surface in use is preferably embossed. More specifically, a surface of the fluoropolymer sheet of the solar cell encapsulant sheet which is to be a light-receiving surface of a produced flexible solar cell module is preferably embossed.

The embossed pattern reduces the reflection loss of sunlight, prevents glare, and improves the appearance.

The embossed pattern may consist of peaks and valleys arranged in a regular pattern or peaks and valleys arranged in a random fashion.

The embossed pattern may be formed before or after adhering the solar cell encapsulant sheet to the solar cell element, or may be formed at the same time as adhering to the solar cell element. Preferably, the embossed pattern is formed before adhering to the solar cell element in order to prevent the surface from being non-uniformly embossed and provide a uniformly embossed pattern.

However, in the case that a solar cell encapsulant sheet with an already embossed surface is used to encapsulate a flexible solar cell element by roll-to-roll processing, part of the embossed pattern will be lost during the thermocompression bonding process for encapsulation. For this reason, a commonly used strategy is to emboss the surface of a solar cell encapsulant sheet after encapsulating a flexible solar cell element.

In contrast, even when a solar cell encapsulant sheet with an already embossed surface is used to encapsulate a flexible solar cell element by roll-to-roll processing in accordance with the method for producing a flexible solar cell module of the present invention, it is possible to avoid loss of the embossed pattern. This is presumably because the adhesive layer has a sufficiently high viscoelastic storage modulus as well as sufficient adhesion strength.

The surface of the solar cell encapsulant sheet may be embossed by any methods, and a preferred example of embossing methods is a method in which in the process of simultaneously forming the adhesive layer and the fluoropolymer sheet of the solar cell encapsulant sheet by coextrusion, an embossing roll is used as a chill roll to emboss the surface while cooling the molten resin.

The solar cell element commonly includes a photoelectric conversion layer that generates electrons when receiving light, an electrode layer that draws generated electrons, and a flexible substrate.

The photoelectric conversion layer may be made of, for example, a crystalline semiconductor (e.g. monocrystal silicon, monocrystal germanium, polycrystal silicon, microcrystal silicon), an amorphous semiconductor (e.g. amorphous silicon), a compound semiconductor (e.g. GaAs, InP, AlGaAs, Cds, CdTe, Cu₂S, CuInSe₂, CuInS₂), or an organic semiconductor (e.g. phthalocyanine, polyacetylene).

The photoelectric conversion layer may be a monolayer or a multilayer.

The thickness of the photoelectric conversion layer is preferably 0.5 to 10 μm.

The flexible substrate is not particularly limited, provided that it is flexible and suited for flexible solar cells. Examples thereof include substrates made of a heat resistant resin such as polyimide, polyether ether ketone, or polyethersulfone.

The thickness of the flexible substrate is preferably 10 to 80 μm.

The electrode layer is a layer made of an electrode material.

The electrode layer may be formed on the photoelectric conversion layer, between the photoelectric conversion layer and the flexible substrate, or on the flexible substrate, according to need.

The solar cell element may have two or more electrode layers.

The electrode layer is preferably a transparent electrode when located on the light-receiving surface side because it is required to allow light to pass through. The electrode material is not particularly limited, provided that it is a common transparent electrode material such as a metal oxide. Preferred examples thereof include ITO and ZnO.

In the case that it is not a transparent electrode, it may be a metal (e.g. silver) patterned bus electrode or a metal (e.g. silver) patterned finger electrode, which is used with a bus electrode.

In the case that the electrode layer is located on the back side, it is not necessarily transparent and may be made of a common electrode material. The electrode material, however, is preferably silver.

The solar cell element is produced by any common methods, and examples thereof include a known method in which the photoelectric conversion layer and electrode layers are stacked on the flexible substrate.

The solar cell element may be a long sheet wound into a roll or a rectangular sheet.

The method for producing a flexible solar cell module of the present invention includes thermocompression bonding of the solar cell encapsulant sheet to at least the light-receiving surface of the solar cell element by pressing the solar cell encapsulant sheet and the solar cell element between a pair of heating rolls.

The light-receiving surface of the solar cell element is a surface that generates electric power from received light, and refers to the photoelectric conversion layer-side surface and not to the flexible substrate-side surface.

In the method for producing a flexible solar cell module of the present invention, the thermocompression bonding is preferably accomplished by stacking the solar cell element and the solar cell encapsulant sheet such that the photoelectric conversion layer-side surface of the solar cell element faces the surface of the adhesive layer of the solar cell encapsulant sheet, and pressing them by a pair of heating rolls.

The temperature of the heating rolls used in the pressing process is preferably 80 to 160° C. If the heating roll temperature is lower than 80° C., adhesion failure may occur. If the heating roll temperature is higher than 160° C., wrinkles are likely to occur by the thermocompression bonding. The more preferable heating roll temperature is 90 to 120° C.

The rotation speed of the heating rolls is preferably 0.1 to 10 m/min. If the rotation speed of the heating rolls is less than 0.1 m/min, wrinkles are likely to occur after the thermocompression bonding. If the rotation speed of the heating rolls is more than 10 m/min, adhesion failure may occur. The rotation speed of the heating rolls Is more preferably 0.3 to 5 m/min.

Because of the presence of the above-described specific resin in the adhesive layer of the solar cell encapsulant sheet, the method for producing a flexible solar cell module of the present invention allows any crosslinking processes to be omitted, and therefore allows short-term thermocompression bonding. Additionally, the thermocompression bonding can be carried out at low temperatures. Therefore, the method can prevent wrinkles and curls while ensuring sufficient adhesion between the solar cell element and the solar cell encapsulant sheet. Consequently, flexible solar cell modules can be efficiently produced by roll-to-roll processing.

The following description is offered to specifically illustrate the method for producing a flexible solar cell module of the present invention using FIG. 1.

As shown in FIG. 1, a solar cell element A and a solar cell encapsulant sheet B are both long sheets wound into a roll. First, the solar cell element A and the solar cell encapsulant sheet B are unrolled such that the light-receiving surface of the solar cell element A faces the adhesive layer surface of the solar cell encapsulant sheet, and stacked to form a laminate sheet C.

Subsequently, the laminate sheet C is inserted between a pair of rolls D that are heated to a predetermined temperature, and the solar cell element A and the solar cell encapsulant sheet B are adhered to and integrated with each other by thermocompression bonding in which the laminate sheet C is heated and pressed in the thickness direction. Consequently, the solar cell element is encapsulated with the solar cell encapsulant sheet, thereby providing a flexible solar cell module E.

FIG. 2 is a vertical cross-sectional view schematically showing an exemplary solar cell element A used in the method for producing a flexible solar cell module of the present invention, and FIG. 3 is a vertical cross-sectional view schematically showing an exemplary solar cell encapsulant sheet B used in the method for producing a flexible solar cell module of the present invention. As shown in FIG. 2, the solar cell element A includes a photoelectric conversion layer 2 on a flexible substrate 1. It should be noted that electrode layers are omitted because many variations of arrangements thereof are possible. As shown in FIG. 3, the solar cell encapsulant sheet B includes a fluoropolymer sheet 4 and an adhesive layer 3.

FIG. 4 is a vertical cross-sectional view schematically showing an exemplary flexible solar cell module produced by the production method of the present invention.

The photoelectric conversion layer 2-side surface of the solar cell element A is encapsulated with the adhesive layer 3 of the solar cell encapsulant sheet B, as shown in FIG. 4, so that the flexible solar cell module E, an integrated laminate of the solar cell element A and the solar cell encapsulant sheet B, is obtained.

The method for producing a flexible solar cell module of the present invention may further include thermocompression bonding of the solar cell encapsulant sheet to the flexible substrate-side surface of the solar cell element by pressing the solar cell encapsulant sheet and the solar cell element between the heating rolls.

When the flexible substrate-side surface (back surface) of the solar cell element is encapsulated as well as the photoelectric conversion layer-side surface (front surface), the solar cell element is encapsulated more favorably. In this case, the resulting flexible solar cell module can stably generate electric power for a longer time.

The thermocompression bonding of the solar cell encapsulant sheet to the flexible substrate-side surface (back surface) can be accomplished by methods such as a thermocompression bonding method in which the solar cell encapsulant sheet is set such that the adhesive layer of the solar cell encapsulant sheet faces the flexible substrate-side surface (back surface) of the solar cell element, and they are pressed between a pair of heating rolls in the same manner as described above.

In the case that the flexible substrate-side surface of the solar cell element is encapsulated, a solar cell encapsulant sheet including an adhesive layer and a metal plate may be used because light transmitting properties are not required.

Examples of this adhesive layer include the same adhesive layers as those described above for the solar cell encapsulant sheet.

Examples of the metal plate include plates of stainless steel and plates of aluminum.

The thickness of the metal plate is preferably 25 to 800 μm.

In the case that the flexible substrate-side surface (back surface) of the solar cell element is encapsulated with the adhesive layer and the metal plate, the encapsulation can be accomplished by, for example, forming a sheet of the adhesive layer and the metal plate, and thermocompression bonding of the sheet of the adhesive layer and the metal plate to the flexible substrate-side surface (back surface) of the solar cell element, that is, thermocompression bonding of the flexible substrate and the adhesive layer in the manner described above.

The thermocompression bonding process of the solar cell encapsulant sheet or the sheet of the adhesive layer and the metal plate to the flexible substrate-side surface (back surface) of the solar cell element may be carried out before, after, or at the same time as the above-described thermocompression bonding process of the solar cell encapsulant sheet to the light-receiving surface of the solar cell element.

The following description is offered to illustrate, using FIG. 5, one example of the method for producing a flexible solar cell module of the present invention in which the photoelectric conversion layer-side surface (front surface) and the flexible substrate-side surface (back surface) of a solar cell element are simultaneously encapsulated.

Specifically, in addition to a long solar cell element A wound into a roll, two long solar cell encapsulant sheets wound into rolls are prepared. As shown in FIG. 5, the long solar cell encapsulant sheets B and B are unrolled while the long solar cell element A is also unrolled. The solar cell encapsulant sheets B and B are set such that the adhesive layers of the two sheets face each other, and stacked with the solar cell element A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell element A is encapsulated between the solar cell encapsulant sheets B and B. In this manner, a flexible solar cell module F is formed in a continuous manner.

In the method for producing a flexible solar cell module, the pressing of the laminate sheet C in the thickness direction under heating may be performed at the same time as the formation of the laminate sheet C by stacking the solar cell encapsulant sheets B and B with the solar cell element A sandwiched therebetween.

FIG. 6 shows one example of production of a flexible solar cell module in the case of using rectangular solar cell elements.

Specifically, rectangular sheets of a solar cell element A with a predetermined size are prepared instead of the long solar cell element wound into a roll. As shown in FIG. 6, the long solar cell encapsulant sheets B and B are unrolled such that the adhesive layers of these sheets face each other, and the solar cell elements A are delivered between the solar cell encapsulant sheets B and B at regular time intervals. Thus, the solar cell encapsulant sheets B and B are stacked with the solar cell elements A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell elements A are encapsulated between the solar cell encapsulant sheets B and B. In this manner, flexible solar cell modules F are formed in a continuous manner.

In the method for producing a flexible solar cell module, the pressing of the laminate sheet C in the thickness direction under heating may be performed at the same time as the formation of the laminate sheet C.

FIGS. 7 and 8 show examples of flexible solar cell modules produced by encapsulating the photoelectric conversion layer-side surface (front surface) and the flexible substrate-side surface (back surface) of a solar cell element by the method for producing a flexible solar cell module of the present invention.

FIG. 7 is a vertical cross-sectional view schematically showing one example of a flexible solar cell module F in which the photoelectric conversion layer 2-side surface and the flexible substrate 1-side surface of a solar cell element A are encapsulated with adhesive layers 3 of solar cell encapsulant sheets B.

FIG. 8 is a vertical cross-sectional view schematically showing one example of a flexible solar cell module G in which the photoelectric conversion layer 2-side surface of a solar cell element A is encapsulated with an adhesive layer 3 of a solar cell encapsulant sheet B, and the flexible substrate 1-side surface is encapsulated with a sheet including an adhesive layer 3 and a metal plate 5.

As described above, the method for producing a flexible solar cell module of the present invention is characterized by encapsulating a solar cell element with a solar cell encapsulant sheet having specific features.

The method can suitably produce flexible solar cell modules in which a solar cell element and a solar cell encapsulant sheet are well adhered to each other by roll-to-roll processing without causing wrinkles and curls.

### Advantageous Effects of Invention

Because of the features described above, the method for producing a flexible solar cell module of the present invention makes it possible to suitably produce flexible solar cell modules in which a solar cell element and a solar cell encapsulant sheet are well adhered to each other by encapsulating a solar cell element by roll-to-roll processing in a continuous manner without the need to perform a crosslinking process and without causing wrinkles and curls.

### BRIEF DESCRIPTION OF DRAWINGS

FIG. 1 is a schematic view showing one example of production by the method for producing a flexible solar cell module of the present invention;

FIG. 2 is a vertical cross-sectional view schematically showing an exemplary solar cell element used in the method for producing a flexible solar cell module of the present invention;

FIG. 3 is a vertical cross-sectional view showing an exemplary solar cell encapsulant sheet used in the method for producing a flexible solar cell module of the present invention;

FIG. 4 is a vertical cross-sectional view showing an exemplary flexible solar cell module produced by the method for producing a flexible solar cell module of the present invention;

FIG. 5 is a schematic view showing one example of production by the method for producing a flexible solar cell module of the present invention;

FIG. 6 is a schematic view showing one example of production by the method for producing a flexible solar cell module of the present invention;

FIG. 7 is a vertical cross-sectional view showing an exemplary flexible solar cell module produced by the method for producing a flexible solar cell module of the present invention;

FIG. 8 is a vertical cross-sectional view showing an exemplary flexible solar cell module produced by the method for producing a flexible solar cell module of the present invention;

FIG. 9 is a schematic view showing an exemplary peak-valley pattern on the surface of a chill roll in an exemplary device for producing solar cell encapsulant sheets;

FIG. 10 is a schematic view showing an exemplary embossed surface of a solar cell encapsulant sheet; and

FIG. 11 is a schematic view showing an exemplary embossing device for solar cell encapsulant sheets.

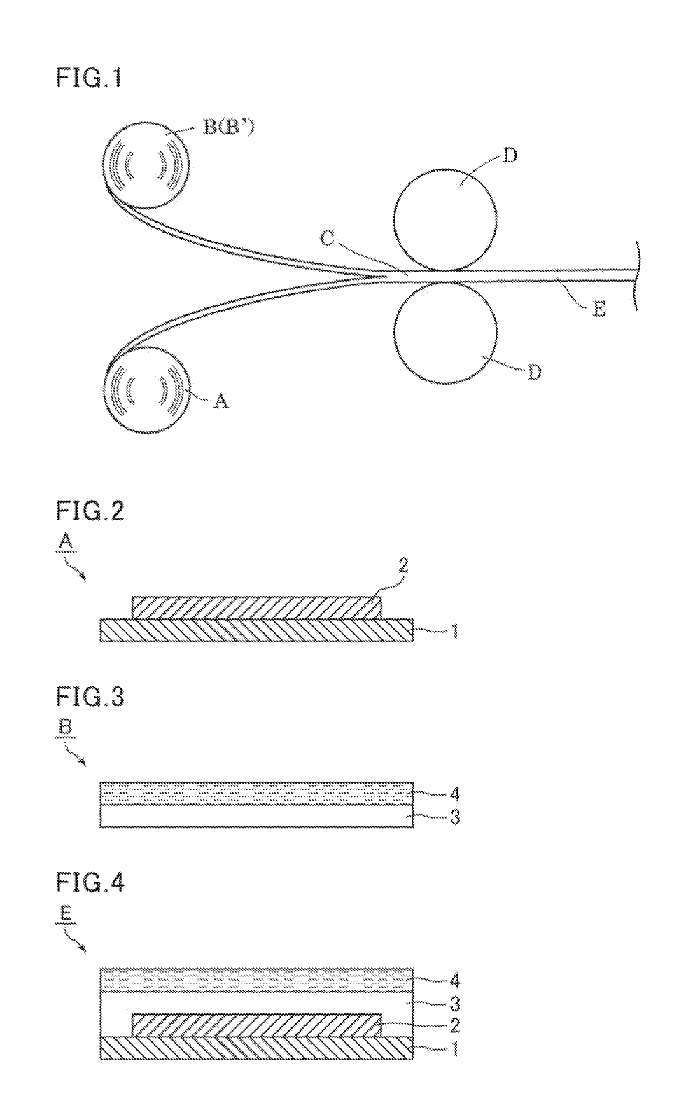

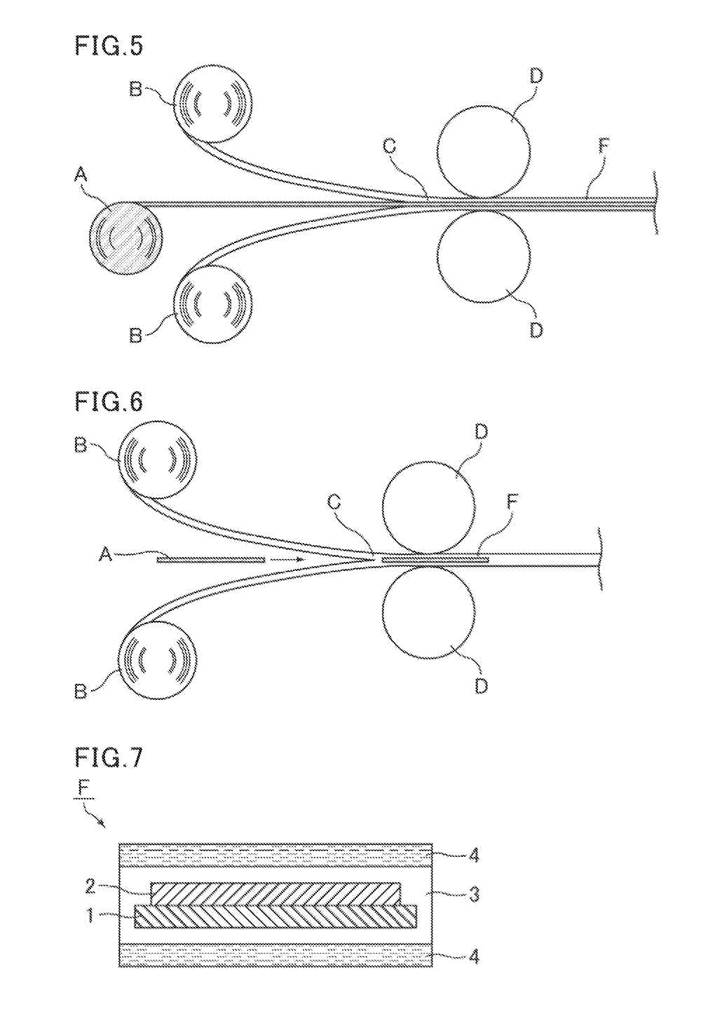

### DESCRIPTION OF EMBODIMENTS

The following examples are offered to illustrate the present invention in more detail, but are not to be construed as limiting the present invention.

### EXAMPLES 1 TO 12 AND COMPARATIVE EXAMPLES 2 AND 3

An adhesive layer composition that contained 100 parts by weight of an ethylene-unsaturated carboxylic acid copolymer or an ionomer thereof containing predetermined amounts of units (shown in Tables 1, 2 and 3), and a predetermined amount of a silane compound (shown in Tables 1, 2 and 3) selected from 3-glycidoxypropyltrimethoxysilane (trade name: “Z-6040”, available from Dow Corning Toray Co., Ltd.), 2-(3,4-epoxycyclohexyl)ethyltrimethoxysilane (trade name: “Z-6043”, available from Dow Corning Toray Co., Ltd.) and N-2-(aminoethyl)-3-aminopropylmethyldimethoxysilane (trade name: “KBM-602”, available from Shin-Etsu Chemical Co., Ltd.) was molten and kneaded in a first extruder at 250° C.

Separately, a predetermined fluoropolymer selected from polyvinylidene fluoride (trade name: “Kynar 720”, available from Arkema), a vinylidene fluoride-hexafluoropropylene copolymer (trade name: “Kynar Flex 2800”, available from Arkema), a mixture of vinylidene fluoride and polymethylmethacrylate (a mixture containing 100 parts by weight of “Kynar 720” (trade name, available from Arkema) and 20 parts by weight of polymethylmethacrylate) and a tetrafluoroethylene-ethylene copolymer (trade name: Neoflon ETFE, available from Daikin Industries Ltd.) as shown in Tables 1, 2 and 3 was molten and kneaded in a second extruder at 230° C.

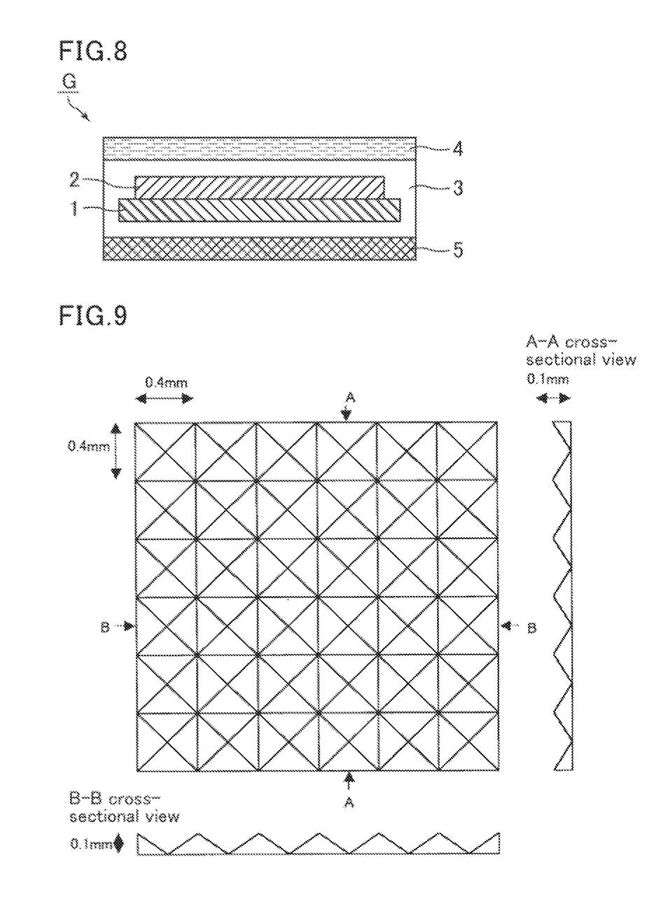

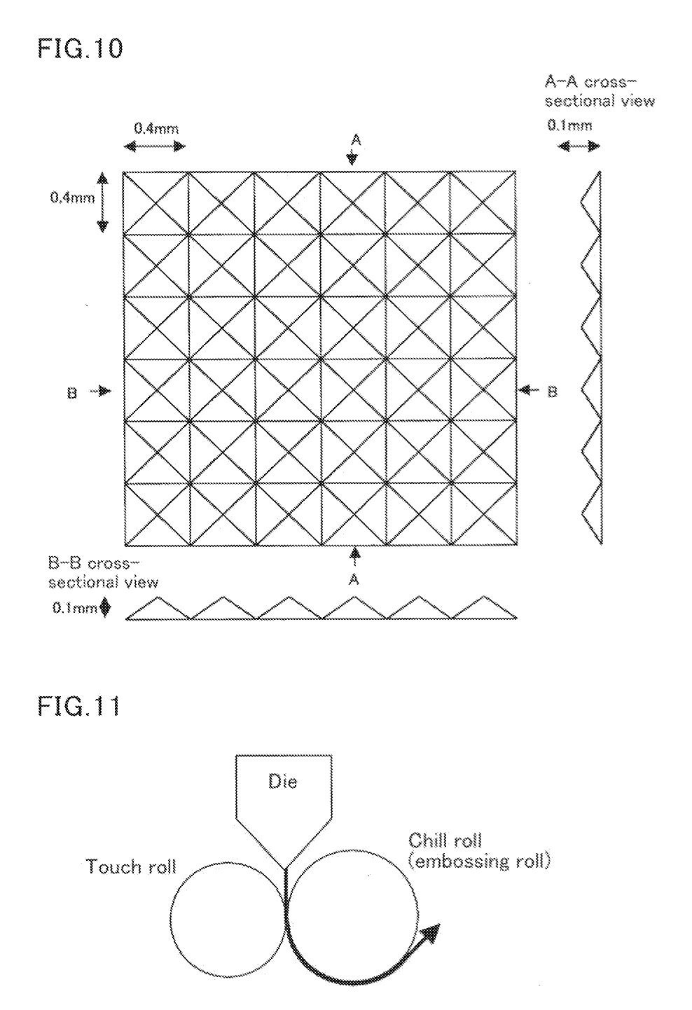

The adhesive layer composition and the vinylidene fluoride were supplied to a coalescent die connecting the first extruder and the second extruder where they were contacted, and then extruded from a T die connected to the coalescent die into a sheet that consisted of a 0.3 mm-thick adhesive layer and a 0.03 mm-thick fluoropolymer layer. In this process of forming the sheet by extrusion from the T die, peaks and valleys arranged in a regular pattern as shown in FIG. 10 were formed on the surface of the fluoropolymer layer by a chill roll having a regular pattern of peaks and valleys on the surface as shown in FIG. 9. In this manner, a surface-embossed, long solar cell encapsulant sheet of a predetermined width was obtained as an integrated laminate which consisted of an adhesive layer made of the adhesive layer composition and a fluoropolymer layer on the surface of the adhesive layer.

FIG. 11 shows a layout of the embossing roll in a sheet production system.

Tables 1, 2 and 3 show the melt flow rates (MFR) and the maximum peak temperatures (Tm) determined from endothermic curves obtained by differential scanning calorimetry analysis of the ethylene-unsaturated carboxylic acid copolymers and the ionomers of ethylene-unsaturated carboxylic acid copolymers.

Subsequently, the solar cell encapsulant sheets obtained above were used to produce flexible solar cell modules in the manner described below. First, as shown in FIG. 6, a rectangular sheet that consisted of a flexible substrate made of a flexible polyimide film and a photoelectric conversion layer made of an amorphous silicon thin film on the flexible substrate was prepared as a solar cell element A, and two rolls of a solar cell encapsulant sheet obtained above were prepared as solar cell encapsulant sheets B.

Next, as shown in FIG. 6, the rolls of the long solar cell encapsulant sheets B and B were unrolled, and the solar cell element A was delivered between the solar cell encapsulant sheets B and B that were set such that their adhesive layers faced each other. The solar cell encapsulant sheets B and B were stacked with the solar cell element A sandwiched therebetween to form a laminate sheet C. The laminate sheet C was delivered between a pair of rolls D and D heated to a temperature shown in Tables 1, 2 and 3, and pressed in the thickness direction under heating so that the solar cell encapsulant sheets B and B were adhered to and integrated with each other with the solar cell element A encapsulated therebetween. In this manner, a flexible solar cell module F was produced.

### COMPARATIVE EXAMPLE 1

A flexible solar cell module was formed in the same manner as in Example 1, except that EVA shown in Table 3 was used instead of using an ethylene-unsaturated carboxylic acid copolymer or an ionomer thereof, and that the temperature of the rolls used for encapsulation was changed as shown in Table 3.

### (Evaluation)

The flexible solar cell modules thus obtained were analyzed for occurrence of wrinkles and curls, peeling strength, and resistance to high-temperature, high-humidity conditions in the following manner. Tables 1, 2 and 3 show the results.

### <Occurrence of Wrinkles>

The flexible solar cell modules obtained above were visually evaluated for occurrence of wrinkles and scored based on the following criteria. The ratings of 4 or higher are regarded as being acceptable.
5: No wrinkles were observed.
4: The number of 0.5-mm or shorter winkles observed per unit length (m) was 1.
3: The number of 0.5-mm or shorter winkles observed per unit length (m) was 2 to 4.
2: The number of 0.5-mm or shorter winkles observed per unit length (m) was 5 or more.
1: Large wrinkles with a length of 0.5 mm or more were observed.

### <Occurrence of Curls>

A 500 mm×500 mm piece of each flexible solar cell module was placed on a flat surface, and measured for the height of an edge part curling up from the flat surface.
⊚ (Double circle): less than 20 mm
◯ (Circle): 20 mm or more and less them 25 mm
Δ (Triangle): 25 mm or more and less than 35 mm
× (Cross): 35 mm or more

### <Peeking Strength>

Each flexible solar cell module obtained above was measured for the peeling strength by peeling the solar cell encapsulant sheet from the flexible substrate of the solar cell in accordance with JIS K6854.

### <Resistance to High-Temperature, High-Humidity Conditions>

Each flexible solar cell module obtained above was left at 85° C. and a relative humidity of 85% as specified in JIC C8991, and measured for the time from when the solar cell module was allowed to stand in this environment to when the solar cell encapsulant sheet began to come off from the flexible substrate of the solar cell.

TABLE 1

| | | Example 1 | Example 2 | Example 3 | Example 4 | Example 5 | Example 6 |
|---|---|---|---|---|---|---|---|
| Fluoropolymer | | PVDF | PVDF | PVDF | PVDF | PVDF | PVDF |
| Extrusion temperature | | 250° C. | 230° C. | 250° C. | 230° C. | 250° C. | 250° C. |
| Ethylene- | Ethylene units | 85 | 85 | 80 | 75 | 80 | 85 |
| unsaturated | (% by weight) | | | | | | |
| carboxylic | Unsaturated carboxylic | Acrylic | Methacrylic | Methacrylic | Methacrylic | Methacrylic | Acrylic |
| acid | acid units | acid | acid | acid | acid | acid | acid |
| copolymer or | (% by weight) | 15 | 15 | 20 | 25 | 10 | 15 |
| ionomer | Acrylic acid ester units | — | — | — | — | Isobutyl acrylate | — |
| | (% by weight) | — | — | — | — | 10 | — |
| | Degree of neutralization | — | 23(Zn) | 20(Na) | 20(Zn) | 20(Zn) | — |
| | (mol %) (metal species) | | | | | | |
| | MFR (g/10 min) | 5 | 2 | 2 | 5 | 2 | 5 |
| | Tm (° C.) | 90 | 80 | 85 | 80 | 85 | 90 |
| EVA | Vinyl acetate | — | — | — | — | — | — |
| | (% by weight) | | | | | | |
| | MFR (g/10 min) | — | — | — | — | — | — |
| | Tm (° C.) | — | — | — | — | — | — |

| | | | | | | |
|---|---|---|---|---|---|---|
| 3-Glycidoxpropyltrimethoxysilane (parts | 0.5 | — | 0.5 | 0.5 | 0.5 | 0.5 |
| by weight) | | | | | | |
| 2-(3,4-Epoxycyclohexyl)ethyltrimethoxysilane | — | — | — | — | — | — |
| (parts by weight) | | | | | | |
| N-2-(Aminoethyl)-3-aminopropylmethoxysilane | — | 0.5 | — | — | — | — |
| Roll temperature (° C.) | 90 | 90 | 90 | 90 | 90 | 90 |
| Rotation speed (m/min) | 0.5 | 0.5 | 0.5 | 0.5 | 0.5 | 0.5 |
| Wrinkles | 5 | 5 | 5 | 5 | 5 | 5 |
| Curls | ⊚ | ⊚ | ⊚ | ⊚ | ⊚ | ⊚ |
| Peeling strength | 80 N/cm | 80 N/cm | 80 N/cm | 80 N/cm | 80 N/cm | 80 N/cm |
| | or higher | or higher | or higher | or higher | or higher | or higher |
| Resistance to high temperature and high | 3000 H | 2000 H | 3000 H | 3000 H | 3000 H or | 3000 H |
| humidity | or lower | or lower | or lower | or lower | lower | or lower |

TABLE 2

| | | Example 7 | Example 8 | Example 9 | Example 10 | Example 11 | Example 12 |
|---|---|---|---|---|---|---|---|
| Fluoropolymer | | PVDF- | PVDF/ | PVDF | ETFE | PVDF | PVDF |
| | | HFP | PMMA | | | | |
| Extrusion temperature | | 230° C. | 250° C. | 250° C. | 290° C. | 250° C. | 250° C. |
| Ethylene- | Ethylene units | 85 | 80 | 80 | 85 | 80 | 80 |
| unsaturated | (% by weight) | | | | | | |
| carboxylic | Unsaturated carboxylic | Methacrylic | Methacrylic | Methacrylic | Methacrylic | Methacrylic | Methacrylic |
| acid | acid units | acid | acid | acid | acid | acid | acid |
| copolymer or | (% by weight) | 15 | 20 | 10 | 15 | 10 | 10 |
| ionomer | Acrylic acid ester units | — | — | Isobutyl acrylate | — | Isobutyl acrylate | Isobutyl acrylate |
| | (% by weight) | — | — | 10 | — | 20 | 30 |
| | Degree of neutralization | 23(Zn) | 20(Na) | 20(Zn) | 23(Zn) | 20(Zn) | 20(Zn) |
| | (mol %) (metal species) | | | | | | |
| | MFR (g/10 min) | 5 | 2 | 2 | 5 | 2 | 2 |
| | Tm (° C.) | 90 | 85 | 75 | 90 | 75 | 85 |
| EVA | Vinyl acetate | — | — | — | — | — | — |
| | (% by weight) | | | | | | |
| | MFR (g/10 min) | — | — | — | — | — | — |
| | Tm (° C.) | — | — | — | — | — | — |

| | | | | | | |
|---|---|---|---|---|---|---|
| 3-Glycidoxpropyltrimethoxysilane (parts | — | — | — | — | 0.5 | 0.5 |
| by weight) | | | | | | |
| 2-(3,4-Epoxycyclohexyl)ethyltrimethoxysilane | — | — | — | 0.5 | — | — |
| (parts by weight) | | | | | | |
| N-2-(Aminoethyl)-3-aminopropylmethoxysilane | — | — | — | — | — | — |
| Roll temperature (° C.) | 90 | 90 | 90 | 90 | 90 | 90 |
| Rotation speed (m/min) | 0.5 | 0.5 | 0.5 | 0.5 | 0.5 | 0.5 |
| Wrinkles | 5 | 5 | 5 | 5 | 5 | 5 |
| Curls | ⊚ | ⊚ | ⊚ | ⊚ | ⊚ | ⊚ |
| Peeling strength | 70 N/cm | 70 N/cm | 70 N/cm | 70 N/cm | 80 N/cm | 80 N/cm |
| | or higher | or higher | or higher | or higher | or higher | or higher |
| Resistance to high temperature and high | 3000 H | 3000 H | 3000 H | 3000 H | 2000 H | 1500 H |
| humidity | or lower | or lower | or lower | or lower | or lower | or lower |

TABLE 3

| | | Comparative | Comparative | Comparative |
|---|---|---|---|---|
| | | Example 1 | Example 2 | Example 3 |
| Fluoropolymer | | PVDF | PVDF | PVDF |
| Extrusion temperature | | 250° C. | 250° C. | 280° C. |
| Ethylene-unsaturated | Ethylene units (% by weight) | — | 91.5 | 91.5 |
| carboxylic acid | Unsaturated carboxylic acid units | — | Methacrylic acid | Methacrylic acid |
| copolymer or ionomer | (% by weight) | — | 8.5 | 8.5 |
| | Acrylic acid ester units | — | — | — |
| | (% by weight) | — | — | — |
| | Degree of neutralization (mol %) (metal species) | — | 17(Zn) | 17(Zn) |
| | MFR (g/10 min) | — | 5.5 | 5.6 |
| | Tm (° C.) | — | 98 | 98 |
| EVA | Vinyl acetate (% by weight) | 27 | — | — |
| | MFR (g/10 min) | 30 | — | — |
| | Tm (° C.) | 70 | — | — |

| | | | |
|---|---|---|---|
| 3-Glycidoxypropyltrimethoxysilane (parts by weight) | 0.5 | — | — |
| 2-(3,4-Epoxycyclohexyl)ethyltrimethoxysilane (parts by weight) | — | — | — |
| N-2-(Aminoethyl)-3-aminopropylmethyldimethoxysilane (parts by weight) | — | — | — |
| Boil temperature (° C.) | 85 | 80 | 120 |
| Rotation speed (m/min) | 0.5 | 0.5 | 0.5 |
| Wrinkles | 1 | 6 | 1 |
| Curls | X | ◯ | X |
| Peeling strength | 10 N/cm or higher | 20 N/cm or lower | 70 N/cm or higer |
| Resistance to high temperature and high humidity | 1000 H | 1000 H | 3000 H or [symbol] |

[symbol]

indicates data missing or illegible when filed

### INDUSTRIAL APPLICABILITY

The method for producing a flexible solar cell module of the present invention makes it possible to suitably produce flexible solar cell modules in which a solar cell element and a solar cell encapsulant sheet are well adhered to each other by roll-to-roll processing without causing wrinkles and curls.

### REFERENCE SIGNS LIST

A Solar cell element
B, B′ Solar cell encapsulant sheet
C Laminate sheet
D Roll
E, F, G Flexible solar cell module
1 Flexible substrate
2 Photoelectric conversion layer
3 Adhesive layer
4 Fluoropolymer sheet
5 Metal plate

1. A method for producing a flexible solar cell module, comprising thermocompression bonding of a solar cell encapsulant sheet to at least a light-receiving surface of a solar cell element that comprises a flexible substrate and a photoelectric conversion layer on the flexible substrate by pressing the solar cell encapsulant sheet and the solar cell element together between a pair of heating rolls,
the solar cell encapsulant sheet comprising a fluoropolymer sheet and an adhesive layer on the fluoropolymer sheet, the adhesive layer comprising at least one ethylene copolymer selected from the group consisting of ethylene-unsaturated carboxylic acid copolymers and ionomers of ethylene-unsaturated carboxylic acid copolymers,
the ethylene copolymer comprising 10 to 25% by weight of unsaturated carboxylic acid units.

2. The method for producing a flexible solar cell module according to claim 1,
wherein the ethylene copolymer further comprises (meth)acrylic acid ester units.

3. The method for producing a flexible solar cell module according to claim 1,
wherein the adhesive layer further comprises a dialkoxysilane and/or a trialkoxysilane.

4. The method for producing a flexible solar cell module according to claim 1,
wherein the fluoropolymer sheet comprises at least one fluoropolymer selected from the group consisting of tetrafluoroethylene-ethylene copolymers, ethylene-chlorotrifluoroethylene resins, polychlorotrifluoroethylene resins, polyvinylidene fluoride resins, tetrafluoroethylene-perfluoroalkyl vinyl ether copolymers, polyvinyl fluoride resins, tetrafluoroethylene-hexafluoropropylene copolymers, vinylidene fluoride-hexafluoropropylene copolymers, and a mixture of polyvinylidene fluoride and polymethylmethacrylate.

5. The method for producing a flexible solar cell module according to claim 1,
wherein the solar cell encapsulant sheet has an embossed surface.

6. The method for producing a flexible solar cell module according to claim 1,
wherein the solar cell encapsulant sheet is an integrated laminate of the fluoropolymer sheet and the adhesive layer that are simultaneously formed and stacked by coextrusion.
